(19) United States
(12) Patent Application Publication
(10) Pub. No.: US 2026/0067003 A1
(43) Pub. Date: Mar. 5, 2026

(54) METHOD AND MEASUREMENT ARRANGEMENT FOR DETERMINING AN ANTENNA FACTOR OF A MONOPOLE ANTENNA

(71) Applicant: Rohde & Schwarz GmbH & Co. KG, Muenchen (DE)

(72) Inventor: Horst Hungrichhaussen, Muenchen (DE)

(21) Appl. No.: 18/821,450

(22) Filed: Aug. 30, 2024

(51) Int. Cl. H04B 17/00; H04B 17/11; H04B 17/21

(52) U.S. Cl. CPC H04B 17/0085; H04B 17/11; H04B 17/21

(57) ABSTRACT

A method for determining an antenna factor of a monopole antenna includes providing an universal artificial antenna and determining its coupling capacitance. A matching device is connected with the universal artificial antenna (UAA) and a scattering parameter associated with the UAA is measured. A calibration adapter replaces the UAA, wherein a scattering parameter associated with the calibration adapter is measured. An input capacitance of the matching device is determined. A monopole antenna is connected with the matching device and the UAA, wherein a scattering parameter associated with the UAA and a scattering parameter associated with the calibration adapter are measured. The calibration adapter replaces the UAA. A capacitance of the monopole antenna is calculated. The antenna factor is determined based on the capacitance of the monopole antenna, the coupling capacitance of the UAA and the input capacitance of the matching device.

### FIELD OF THE DISCLOSURE

Embodiments of the present disclosure relate to a method for determining an antenna factor of a monopole antenna. Further, embodiments of the present disclosure relate to a measurement arrangement for determining an antenna factor of a monopole antenna.

### BACKGROUND

Monopole antennas are inter alia used for radiated emission measurements. In many fields, such as electromagnetic compliance testing, EMC testing, the accuracy of the calibration of a monopole antenna plays an important role. It is therefore necessary to determine an antenna factor and calibrate the monopole antenna accordingly.

In the state of the art, many methods are known for determining the antenna factor of a monopole antenna. One of the most common methods for determining the antenna factor and for calibrating a monopole antenna is the equivalent capacitance substitution method, ECSM. In this method, the monopole antenna is calibrated using an artificial antenna with a capacitor equal to a self-capacitance of the monopole antenna. The monopole antenna is thus replaced by the capacitor. A capacitance of the monopole antenna is then calculated by a formula according to DIN EN 55016-1-6.

However, for determining the antenna factor using the ECSM method, it is important that the artificial antenna matches the monopole antenna, or more precisely, that the capacitor of the artificial antenna has the same capacitance as the monopole antenna. Additionally, the capacitance of the capacitor of the artificial antenna must be known in advance in order to determine the antenna factor of the monopole antenna.

Another disadvantage of the ECSM is that it has limited ability to correct an effective height of the monopole antenna if the monopole antenna is not mounted directly on the ground, but there is a distance between the monopole antenna and the ground, is only possible to a limited extend.

Accordingly, there is a need for an improved method of calculating an antenna factor of a monopole antenna and for calibrating the monopole antenna accordingly.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide a method for determining an antenna factor of a monopole antenna. In an embodiment, the method comprises the following steps:
providing a universal artificial antenna and determining a coupling capacitance of the universal artificial antenna in a first measurement setup;
providing a matching device, connecting the matching device with the universal artificial antenna, thereby obtaining a second measurement setup, and measuring a scattering parameter associated with the universal artificial antenna in the second measurement setup,
providing a calibration adapter, connecting the matching device with the calibration adapter such that the calibration adapter replaces the universal artificial antenna, thereby obtaining a third measurement setup, and measuring a scattering parameter associated with the calibration adapter in the third measurement setup,
determining an input capacitance of the matching device using the ratio of the scattering parameter associated with the universal artificial antenna in the second measurement setup to the scattering parameter associated with the calibration adapter in the third measurement setup;
providing a monopole antenna, connecting the monopole antenna with the matching device and the universal artificial antenna, thereby obtaining a fourth measurement setup, and measuring a scattering parameter associated with the universal artificial antenna in the fourth measurement setup;
providing the calibration adapter, connecting the monopole antenna with the matching device and the calibration adapter such that the calibration adapter replaces the universal artificial antenna, thereby obtaining a fifth measurement setup, and measuring a scattering parameter associated with the calibration adapter in the fifth measurement setup;
determining a capacitance of the monopole antenna based on the coupling capacitance of the universal artificial antenna, the input capacitance of the matching device, and the ratio of the scattering parameter associated with the universal artificial antenna in the fourth measurement setup to the scattering parameter associated with the calibration adapter in the fifth measurement setup; and
determining the antenna factor of the monopole antenna based on the capacitance of the monopole antenna, the coupling capacitance of the universal artificial antenna and the input capacitance of the matching device.

Of course, in other embodiments of the present disclosure, the method can include any one or more steps set forth above in any combination.

Moreover, embodiments of the present disclosure provide a measurement arrangement for determining an antenna factor of a monopole antenna. In an embodiment, the measurement arrangement having different measurement setups, wherein the measurement arrangement comprises a universal artificial antenna, a calibration adapter, a matching device, a monopole antenna and a network analyser, which can be arranged differently so as to obtain the different measurement setups.

In a first measurement setup for determining the capacitance of the universal artificial antenna, the universal artificial antenna is coupled to the calibration adapter.

In a second measurement setup for measuring the scattering parameter associated with the universal artificial antenna, the matching device is coupled to the universal artificial antenna, wherein the matching device and the artificial antenna are coupled to the network analyzer.

In a third measurement setup for measuring the scattering parameter associated with the calibration adapter, the matching device is coupled to the calibration adapter, wherein the matching device and the calibration adapter are coupled to the network analyzer.

In a fourth measurement setup for measuring the scattering parameter associated with the universal artificial antenna, the matching device is coupled to the monopole antenna, wherein the universal artificial antenna is coupled to the monopole antenna, and wherein the universal artificial antenna and the matching device are coupled to the network analyzer.

In a fifth measurement setup for measuring the scattering parameter associated with the calibration adapter, wherein the matching device is coupled to the monopole antenna, wherein the calibration adapter is coupled to the monopole antenna, and wherein the calibration adapter and the matching device are coupled to the network analyzer.

In an embodiment, these five measurement setups are employed to determine the different scattering parameters, based on which the different capacitances can be calculated so as to finally determine the antenna factor of the monopole antenna and to calibrate the monopole antenna accordingly.

As used herein, the term “connecting A with B” is understood to denote that an electrically conductive connection is provided between A and B, such that a signal transmission between A and B via an electrical conductor can be established, for instance via a line, a cable, or a wire.

Likewise, the term “connect” is understood to denote an electrically conductive connection via an electrical conductor, for example without interruption, e.g. a continuous electrical conductor.

The term “coupled to” is understood to denote an electrically conductive connection via an electrical conductor and, thus, it is synonymous to the term “connected to”.

The term “universal artificial antenna” is understood to denote any type of artificial antenna, which does not have to be adjusted to the monopole antenna. In specific, resistors of the universal artificial antenna do not have to equal to the self-capacitance of the monopole antenna.

The term “monopole antenna” is understood to denote monopole antennas of various shapes, such as a rod of a specific length or height and/or a specific diameter, or any other type of monopole antenna. The monopole antennas can be mounted on the ground or on a ground plate that is distant from the ground. If the monopole antenna is mounted on a ground plate distanced from the ground, the monopole antenna must be grounded by an appropriate grounding line.

“Scattering parameters” describe the electrical behaviour of linear electrical networks when undergoing various steady state stimuli by electrical signals, namely a proportion of an incident wave and a reflected wave. For instance, a scattering parameter, S-parameter, of a two-port network has the following generic descriptions: S₁₁ is the input port voltage reflection coefficient, S₁₂ is the reverse voltage gain, S₂₁ is the forward voltage gain and S₂₂ is the output voltage reflection coefficient.

The expression “measuring a scattering parameter” is understood to denote that the scattering parameter is determined based on measured parameters, for instance based on the incident wave and the reflected wave.

The method according to one or more embodiments of the present disclosure is based on the idea that the antenna factor of a monopole antenna can be calculated in a few steps using different measurement setups, also called measurement arrangements, wherein the calculation can be attributed (solely) to scattering parameters measured in different measurement setups. Depending on the measurement setup, the respective scattering parameters measured can be used to determine the capacitance of the monopole antenna, the input capacitance of the matching device and/or the coupling capacitance of the universal artificial antenna, wherein these parameters are taken into account when determining the antenna factor. In other words, measured scattering parameters directly or values calculated based on measured scattering parameters, e.g. the input capacitance of the matching device and/or the capacitance of the monopole antenna, are used in order to calculate the antenna factor and to calibrate the monopole antenna.

These methods have the advantage that the universal artificial antenna does not have to match with the monopole antenna, leading to the advantage that one universal artificial antenna can be used to calibrate various monopole antennas. In addition, the capacitance of the universal artificial antenna is independent of characteristics such as the diameter or the length of the monopole antenna.

As indicated above, the calculation is based, for example, on scattering parameters, resulting in smaller uncertainties in the antenna factor calculation. Consequently, the antenna factor can be determined for different positions, e.g. different heights with respect to ground.

In addition, the method can be used, for example, to determine the capacitance of a rod of the monopole antenna and the antenna factor can be determined for different heights of the monopole antenna.

Generally, the respective measurements can be performed by a network analyser, namely the measurements of the scattering parameters, for example in the different measurement setups.

According to an aspect of the present disclosure, the coupling capacitance of the universal artificial antenna, for example, is determined by coupling the universal artificial antenna to the calibration adapter, thereby obtaining the first measurement setup, and measuring a scattering parameter associated with the universal artificial antenna coupled to the calibration adapter.

Thus, the coupling capacitance of the universal artificial antenna is only based on one measured value, namely on the scattering parameter of the universal artificial antenna coupled to the calibration adapter, namely in the first measurement setup.

Hereinafter, the coupling capacitance relates to the capacitive coupling of the universal artificial antenna with regard to an electromagnetic coupling, for example the transfer of energy within an electrical network or between distant networks by means of displacement current between nodes, induced by the electric field.

In an embodiment, the scattering parameter is measured by a network analyzer that is connected to both the universal artificial antenna and the calibration adapter.

The scattering parameter associated with the universal artificial antenna coupled to the calibration adapter is a transmission factor. For example, the transmission factor is the scattering parameter S₂₁. The transmission factor relates to a forward transmission factor or the forward voltage gain, representative for the transmission without excitation at port 2. For instance, the transmission factor defines the ratio of the output power wave at port 2 to the input power wave at port 1.

In other words, the coupling capacitance of the universal artificial antenna and the calibration adapter is based on the transmission factor, namely scattering parameter S₂₁, which is measured by the network analyzer.

In an aspect of the present disclosure, the capacitance of the universal artificial antenna, for example, is based on the ratio of the scattering parameter associated with the universal artificial antenna coupled to the calibration adapter to the frequency of a measurement signal used, e.g. the scattering parameter measured in the first measurement setup. The scattering parameter itself depends on the frequency of the measurement signal used and, thus, the capacitance of the universal artificial antenna may also depend on the frequency of the measurement signal used. In other words, the capacitance of the universal artificial antenna is based on the scattering parameter associated with the universal artificial antenna coupled to the calibration adapter divided by 2π·f.

In an embodiment, the formula for calculating the coupling capacitance of the universal artificial antenna, which is coupled to the calibration adapter and which are both connected to the network analyzer can be expressed by the following equation:

$${C}_{k} = \frac{{S}_{21 , 1}}{2 π \cdot f} \cdot c$$

wherein Cₖ is the capacitance of the universal artificial antenna, S_{21,1} is the scattering parameter of the universal artificial antenna coupled to the calibration adapter, which is determined in the first measurement setup, f is the frequency of the measurement signal used, and c is a proportionality constant.

In an embodiment, the universal artificial antenna may comprise two 25Ω resistors and a capacitor, and/or wherein the calibration adapter comprises two 25Ω resistors.

In general, it is advisable to use a universal artificial antenna and a calibration adapter with the same number of resistors, for example resistors with the same resistance. This gives an even distribution of the resistors and an overall symmetrical measurement setup for determining the coupling capacitance of the universal artificial antenna in a simplified manner.

Moreover, artificial antennas and calibration adapters having 25Ω resistors are commonly used for calibrating of monopole antennas, e.g. by the ECSM known in the state of the art. These artificial antennas and calibration adapters may also be used for the method according to embodiments of the present disclosure, thereby reducing the efforts required since there is no need to use specific antennas or specific calibration adapters for the method according to the present disclosure.

In a further aspect of the present disclosure, an amplification of the matching device, for example, can be calculated by using the ratio of the scattering parameter associated with the universal artificial antenna to the scattering parameter associated with the calibration adapter. Thus, the amplification and the input capacitance of the matching device can be determined easily based on scattering parameters.

In an embodiment, the input capacitance and the amplification of the matching device are directly proportional to the coupling capacitance of the universal artificial antenna.

In other words, a high coupling capacitance of the universal artificial antenna leads to a high input capacitance and amplification of the matching device, whereas a small coupling capacitance of the universal artificial antenna leads to a small input capacitance of the matching device.

According to another aspect of the present disclosure, the input capacitance of the matching device, for example, is calculated based on the capacitance of the universal artificial antenna and the ratio of the scattering parameter associated with the universal artificial antenna (in the second measurement setup) to the scattering parameter associated with the calibration adapter (in the third measurement setup).

In an embodiment, the capacitance of the matching device may be calculated based on the formula:

$${C}_{e} = ( 1 - \frac{\vert {S}_{21 , 3} \vert}{\vert {S}_{21 , 2} \vert} ) \cdot {C}_{k}$$

wherein Cₑ is the capacitance of the matching device, S_{21,3} is the scattering parameter of the calibration adapter, which is determined in the third measurement setup, S_{21,2} is the scattering parameter of the universal artificial antenna, which is determined in the second measurement setup, and Cₖ is the coupling capacitance of the universal artificial antenna.

In other words, the input capacitance of the matching device can be calculated from the measurement of two scattering parameters, e.g. in two different measurement setups. As indicated above, the scattering parameters are measured with the network analyzer and the coupling capacitance of the universal artificial antenna used is the one previously calculated.

Overall, this formula describes the influence of the matching device on the scattering parameters of the calibration adapter and the universal artificial antenna in a measurement setup where the calibration adapter or the universal artificial antenna is connected to the matching device and to the network analyzer.

According to a further aspect of the present disclosure, the matching device comprises, for example, at least a capacitor, an amplifier and an impedance. The capacitor is associated with an input of the matching device, thereby defining the (input) capacitance of the matching device.

In an embodiment, the capacitance of the capacitor can be calculated using the above formula. The amplification of the amplifier can also be calculated.

In an embodiment, the scattering parameter S_{21,3} associated with the universal artificial antenna and used in the above formula is a transmission factor. This transmission factor is measured with the network analyzer coupled to the universal artificial antenna and the matching device, e.g. the third measurement setup. Thus, in the respective measurement setup, the network analyzer is connected to the universal artificial antenna, whereas the universal artificial antenna is connected to the matching device and the matching device is coupled to the network analyzer.

In an embodiment, the scattering parameter S_{21,2} associated with the calibration adapter is also a transmission factor. This transmission factor is also measured with the network analyzer, which is coupled to the calibration adaptor and the matching device, e.g. the second measurement setup. The second measurement setup is similar to the third measurement setup described above, for that the network analyzer being connected to the calibration adapter instead of the universal artificial antenna.

In another aspect of the present disclosure, the capacitance of the monopole antenna, for example, is determined based on the capacitance of the matching device, the capacitance of the matching device, the scattering parameter associated with the universal artificial antenna, measured when the monopole antenna is connected with the matching device and the universal artificial antenna, and the scattering parameter associated with the calibration adapter, measured when the monopole antenna is connected with the matching device and the calibration adapter.

In other words, the capacitance of the monopole antenna can be calculated based on previously determined capacitances, e.g. coupling capacitance of the universal artificial antenna as well as the input capacitance of the matching device, and scattering parameters determined in different measurement setups, namely the scattering parameter associated with the universal artificial antenna in the fourth measurement setup and the scattering parameter associated with the calibration adapter in the fifth measurement setup.

In an embodiment, the capacitance of the monopole antenna can be calculated based on the following formula:

$${C}_{a} = [ ( 1 - \frac{\vert {S}_{21 , 5} \vert}{\vert {S}_{21 , 5} \vert} ) \cdot {C}_{k} ] - {C}_{e}$$

wherein Cₐ is the capacitance of the monopole antenna, S_{21,5} is the scattering parameter associated with the calibration adapter, which is measured in the fifth measurement setup, S_{21,4} is the scattering parameter associated with the universal artificial antenna, which is measured in the fourth measurement setup, Cₖ is the coupling capacitance of the universal artificial antenna and Cₑ is the input capacitance of the matching device.

Again, the coupling capacitance of the universal artificial antenna as well as the input capacitance of the matching device can be determined based on scattering parameters determined in different measurement setups, namely by using the above formulae.

It is therefore noted, that all the capacitances calculated within methods disclosed herein are based only on measured scattering parameters, so that no further properties of the individual components, namely the monopole antenna, the matching device, the calibration adapter or the universal artificial antenna, are required to determine the antenna factor.

In an embodiment, the monopole antenna may be connected in parallel with the universal artificial antenna.

The term “connected in parallel” is understood to denote that an input and an output port of the monopole antenna may be directly connected with an input and an output port of the universal artificial antenna by an electrical connection. Alternatively, the respective inputs and the respective outputs are connected to associated nodes, respectively. Therefore, the voltage is split between the universal artificial antenna and the monopole antenna.

In another aspect of the present disclosure, the antenna factor of the monopole antenna, for example, is corrected by using a correction factor, wherein the correction factor is calculated by two different ratios, wherein the ratios both depend on the capacitances of the matching device, the universal artificial antenna and the monopole antenna.

Correcting the antenna factor of the monopole antenna ensures the capacitance of the universal artificial antenna is not equal to the self-capacitance of the monopole antenna as it is the case e.g. for the ECSM. In other words, the use of the correction factor in an embodiment allows the use of a universal artificial antenna so that one is not dependent on a specific artificial antenna which matches with the monopole antenna.

It should also be noted that the correction factor is calculated only on the basis of the previously calculated capacitances of the monopole antenna, the universal artificial antenna and the matching device. It is therefore not necessary to know any of these values in advance.

Another advantage is also that the correction factor is also indirectly based only on various measured scattering parameters, which can be measured accurately. This makes the whole method and the calibration of the monopole antenna less sensitive to measurement uncertainties.

In an embodiment of the present disclosure, the correction factor is the product of the ratio of the capacitance of the universal artificial antenna to the sum of the capacitances of the universal artificial antenna and the adjustment unit; and the ratio of the sum of the capacitances of the monopole antenna and the adjustment unit to the capacitance of the monopole antenna.

This leads to the following formula for the correction factor:

$${K}_{c} = \frac{{C}_{k}}{{C}_{k} + {C}_{e}} \cdot \frac{{C}_{a} + {C}_{e}}{{C}_{a}}$$

wherein, K_{c} is the correction factor for correcting the mismatch between the capacitance of the universal artificial antenna and the capacitance of the monopole antenna, Cₖ is the coupling capacitance of the universal artificial antenna, Cₑ is the input capacitance of the matching device and Cₐ is the capacitance of the monopole antenna.

According to a further aspect of the present disclosure, the value of the capacitance of the monopole antenna which is used to calculate the correction factor, for example, is either based on the determined capacitances of the matching device, the universal artificial antenna and the monopole antenna or is calculated according to a geometric model.

The correction factor is calculated by the geometric model for specific monopole antennas. In an embodiment, the monopole antenna is a cylindrical monopole antenna.

In an embodiment, the antenna factor of the monopole antenna may also depend on a height of the monopole antenna above ground potential. Hereinafter, the “height of the monopole antenna” is the effective height of the monopole antenna relative to a ground.

According to the unsymmetrical nature of monopole antennas, a monopole antenna cannot suppress common mode currents at all. In contrast, symmetrical antennas with qualified baluns can suppress unwanted common mode effects. Therefore, monopole antennas are typically mounted on ground level or at least with low inductive and short grounding to the absorber lined shielded enclosure. In case, the monopole antenna has to be mounted distanced from the ground, a height correction of the monopole has to be done, in order to improve measurement uncertainties.

Further, the antenna factor may also depend on the scattering parameter associated the universal artificial antenna coupled in parallel with the monopole antenna, namely in the fourth measurement setup.

This leads to the following formula for calculating the antenna factor:

$${F}_{a c} [ \frac{d B}{m} ] = 20 \cdot log \frac{1}{\vert {S}_{21 , 4} \vert} - 20 \cdot log ( 2 ) - 20 \cdot log ( {h}_{e} ) + 20 \cdot log ( {K}_{c} )$$

wherein, F_{ac} is the antenna factor, S_{21,4} is the scattering parameter of the universal artificial antenna coupled to the monopole antenna, which is measured in the fourth measurement setup, hₑ is the effective height of the monopole antenna and K_{c} is the correction factor as described above.

According to another aspect of the present disclosure, the monopole antenna, for example, is fixed to a tripod or a ground plate during the measurement(s). This is needed, in order to determine the effective height of the monopole antenna and to be able to calculate the antenna factor correctly. However, for calculating the antenna factor, it does not make any difference, whether the monopole antenna is fixed to a tripod or a ground plate during measurement. For example, the monopole antenna can be mounted to a tripod in a height of 1 m.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows an ECSM measurement arrangement for determining an antenna factor of a monopole antenna according to the prior art;

FIG. 2 schematically shows an overview of components of a measurement arrangement according to an embodiment of the present disclosure;

FIG. 3 schematically shows an example of a first measurement setup of the measurement arrangement of FIG. 2, which is used for determining a capacitance of the universal artificial antenna;

FIG. 4 schematically shows an example of a coupling of a universal artificial antenna to a calibration adapter according to the first measurement setup of FIG. 3;

FIG. 5 schematically shows an example of a second measurement setup of the measurement arrangement of FIG. 2, which is used for determining a capacitance of the matching device;

FIG. 6 schematically shows an example of a third measurement setup of the measurement arrangement of FIG. 2, which is used for determining a capacitance of the matching device,

FIG. 7 schematically shows the second measurement setup of FIG. 5 as a circuit diagram,

FIG. 8 schematically shows the third measurement setup of FIG. 7 as a circuit diagram;

FIG. 9 schematically shows an example of a fourth measurement setup of the measurement arrangement of FIG. 2, which is used for determining a capacitance of the matching device;

FIG. 10 schematically shows an example of a fifth measurement setup of the measurement arrangement of FIG. 2, which is used for determining a capacitance of the matching device according to the present disclosure; and

FIG. 11 shows schematically a method for determining an antenna factor of a monopole antenna according to an embodiment of the present disclosure, which is done by the measurement arrangement of FIG. 2.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

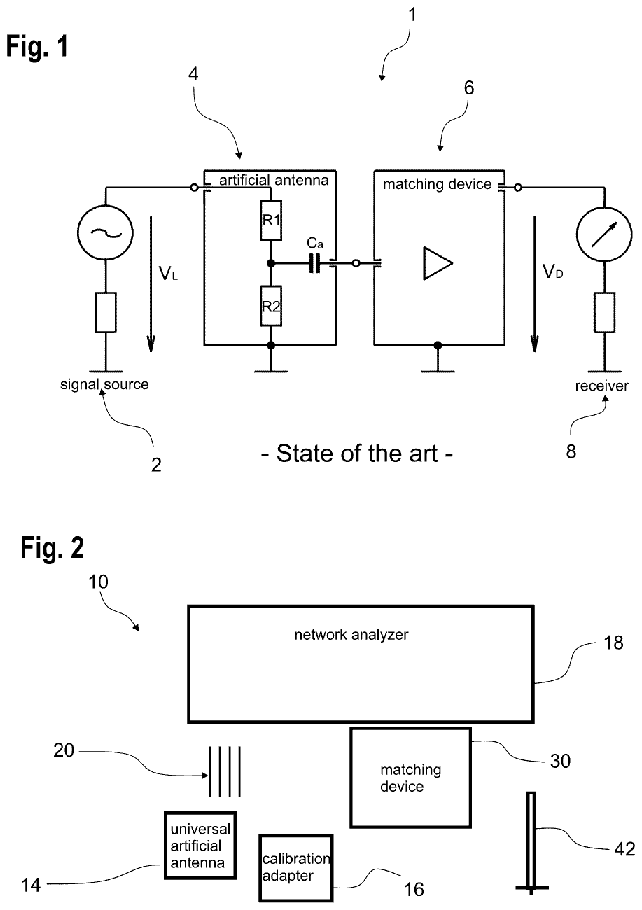

FIG. 1 schematically shows a measurement arrangement, generally designated 1, known in the state of the art, which is used for determining an antenna factor with an equivalent capacitor substitution method (ECSM). As shown in FIG. 1, the measurement arrangement 1 comprises a signal source 2, providing a signal, e.g. a voltage, an artificial antenna 4, replacing a monopole antenna, a matching device 6 with an amplifier and a receiver 8 which receives the signal, namely the voltage.

In the measurement arrangement 1, a monopole antenna is replaced by the artificial antenna 4 that has to correspond to the monopole antenna. Thus, the measurement is not performed with the monopole antenna itself, but with the specific artificial antenna 4.

The artificial antenna 4 comprises two resistors R1 and R2, each having a resistance of 25Ω, which are needed to incorporate a length of the common monopole antenna with the length of 1 m. The ratio of the resistors R1 and R2 is usually 1:1, such that a drive voltage V_{D}, originating from the signal source 2, is divided by the factor of 2, which corresponds to the height correction factor of the monopole antenna of 1 m length.

Further, the artificial antenna 4 comprises a capacitor Cₐ which represents the self-capacitance of the monopole antenna. The self-capacitance of the monopole antenna among others depends on the length of the monopole antenna and/or the diameter of the monopole antenna.

Together with the matching device 6, a capacitive voltage divider is formed. The capacitive voltage divider is followed by an amplifier, which is also contained in the matching device 6. The amplifier has to deliver a V_{L} into a 50Ω load. The gain of the amplifier can be scaled such that an appropriate antenna factor (F_{A}) is obtained by the formula F_{A}=V_{D}−V_{L}.

Thus, in order to calibrate the monopole antenna according to the ECSM method, the artificial antenna 4 has to match with the monopole antenna, which should be calibrated. Therefore, for each monopole antenna a specific artificial antenna 4 is needed.

Moreover, since the height correction depends on the two resistors R1 and R2 of the artificial antenna 4, a height correction is only possible in a limited manner.

Further, there are a number of uncertainties, which can negatively influence the determination of the antenna factor.

In FIGS. 2-10, a measurement arrangement 10 according to one or more embodiments of the present disclosure is shown in different setups which are utilized for determining the antenna factor of a monopole antenna. The measurement arrangement 10 comprises different components which are illustrated in FIG. 2 in an isolated manner, wherein different measurement setups are established based on the components of the measurement arrangement 10 shown in FIG. 2 as will be explained hereinafter in more detail.

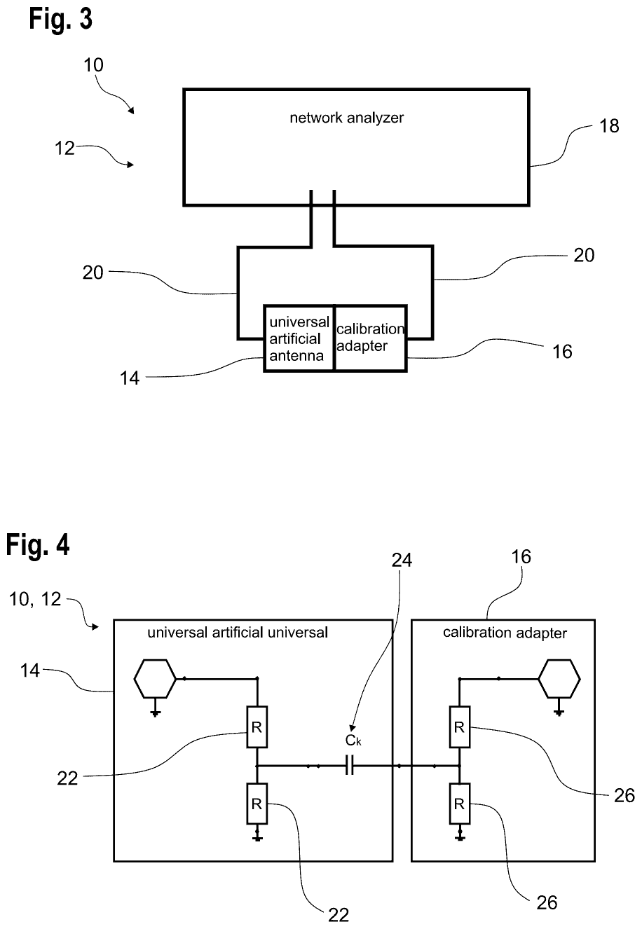

In a first measurement setup 12 of the measurement arrangement 10, which is shown in FIG. 3, a universal artificial antenna 14 is coupled to a calibration adapter 16. The first measurement setup 12 is used to determine the coupling capacitance of the universal artificial antenna 14.

The universal artificial antenna 14 and the calibration adapter 16 are also connected to a network analyzer 18 by lines 20. In an embodiment, the one line 20 connects the universal artificial antenna 14 with a first port of the network analyzer 18, and a second line 20 connects the calibration adapter 16 with a second port of the network analyzer 18. The lines 20 may be realized by electrical conductors, for instance connection cables, for example coaxial cables.

In an embodiment, the network analyzer 18 provides a measurement signal via the first port or the second port which is received by the respective other port of the network analyzer 18. Then, the network analyzer 18 is enabled to analyze the signal received.

In an embodiment, the network analyzer 18 is configured to determine a scattering parameter, S parameter, of the universal artificial antenna 14 coupled to the calibration adapter 16. Generally, the scattering parameter depends on a frequency of the measurement signal used. For example, the scattering parameter of the universal artificial antenna 14 and the calibration adapter 16 determined by the network analyzer 18 is a transmission factor, preferably the scattering parameter S₂₁.

FIG. 4 schematically shows an example of the coupling of the universal artificial antenna 14 with the calibration adapter 16 shown in FIG. 3 in detail, thereby illustrating internal components of the universal artificial antenna 14 and the calibration adapter 16. As shown in FIG. 4, the universal artificial antenna 14 comprises two resistors 22, e.g. having a resistance of 25Ω, and a capacitor 24. The two resistors 22 are connected in row.

In the embodiment shown, the capacitor 24 of the universal artificial antenna 14 is connected to the connection between the two resistors 22, e.g. via a center tap. The capacitor 24 may have a capacity of 15 pF. One side of the capacitor 24 is connected to the center tap located between both resistors 22, whereas the other side of the capacitor 24 is coupled to the calibration adaptor 16.

In an embodiment, the calibration adaptor 16 comprises two resistors 26, e.g. having a resistance of 25Ω, which are also connected in row. The calibration adaptor 16 has an interface via which the calibration adaptor 16 is connected to the universal artificial antenna 14, wherein the interface is associated with a center tap located between both resistors 26.

In the example embodiment, the overall arrangement of the of the two resistors 22 of the universal artificial antenna 14 and the two resistors 26 of the calibration adapter 16 is symmetrical with the capacitor 24 of the universal artificial antenna 14 in the center.

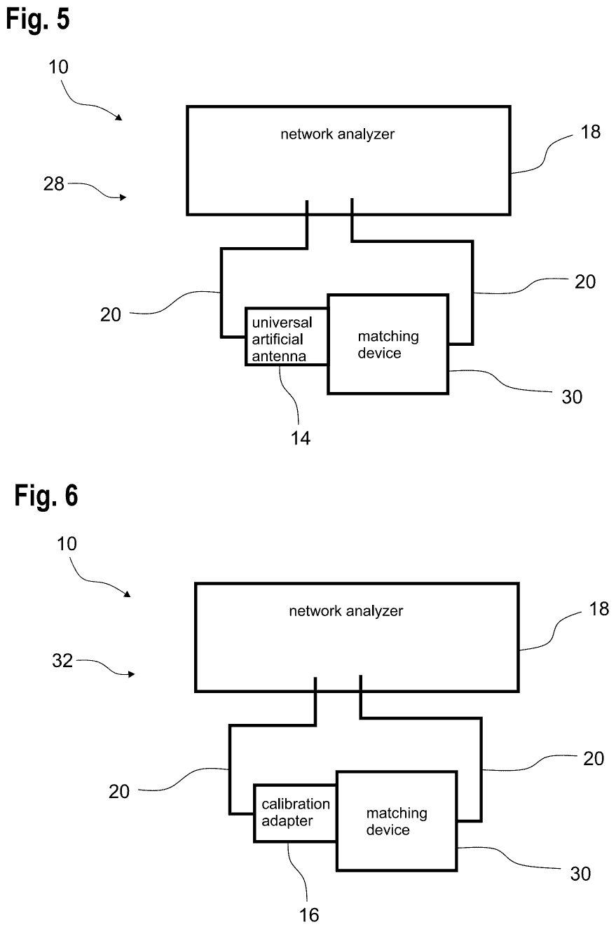

FIG. 5 schematically shows a second measurement setup 28, which comprises the universal artificial antenna 14 and the network analyzer 18. However, in the second measurement setup 28, the universal artificial antenna 14 is connected to a matching device 30 instead of the calibration adapter 16. In other words, the calibration adapter 16 used in the first measurement setup 12 was replaced by the matching device 30.

In the second measurement setup 28, a first port of the network analyzer 18 is connected to the universal artificial antenna 14, whereas the second port of the network analyzer 18 is connected to the matching device 30. With this second measurement setup 28, the influence of the matching device 30 on the scattering factors of the universal artificial antenna 14 can be determined.

In other words, a scattering parameter associated with the universal artificial antenna 14 is measured in the second measurement setup 28. Based on the scattering parameter associated with the universal artificial antenna 14, a capacitance of the matching device 30 can be determined as will be discussed later in more detail.

In an embodiment, the scattering parameter associated with the universal artificial antenna 14 measured in the second measurement setup 28 is again a transmission factor, namely the S-parameter S₂₁.

As it is shown in FIG. 6, a third measurement setup 32 is similar to the second measurement setup 28. The only difference between both setups 28, 32 is that, in the third measurement setup 32, the matching device 30 is coupled to the calibration adapter 16 instead of the universal artificial antenna 14. In other words, the calibration adapter 16 has replaced the universal artificial antenna 14 in the third measurement setup 32 with respect to the second measurement setup 28.

With the third measurement setup 32, the influence of the matching device 30 on the scattering factors of the calibration adapter 16 can be determined. In other words, a scattering parameter associated with the calibration adapter 16 is measured in the third measurement setup 32. Based on the scattering parameter associated with the calibration adapter 16, a capacitance of the matching device 30 can be determined as will be discussed later in more detail. In an embodiment, the scattering parameter associated with the calibration adapter 16 measured in the third measurement setup 32 is again a transmission factor, namely the S-parameter S₂₁.

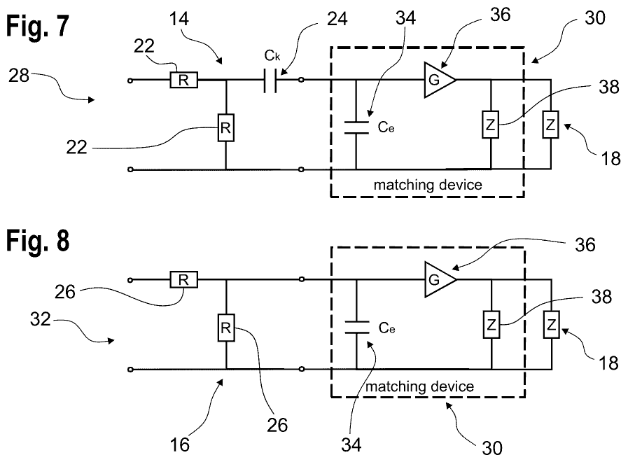

In FIG. 7, the second measurement setup 28 with the universal artificial antenna 14 coupled to the matching device 30 is shown as a circuit diagram, whereas the third measurement setup 32 with the calibration adapter 16 coupled to the matching device 30 is shown in FIG. 8 as a circuit diagram.

As shown in FIGS. 7 and 8, the matching device 30 comprises a capacitor 34, e.g. an input capacitor, the capacitance of which is determined by the second measurement setup 28 and third measurement setup 32. The matching device 30 also comprises an amplifier 36 and an adjustable impedance 38. The amplification of the amplifier 36 may also be determined by the second measurement setup 28 and third measurement setup 32.

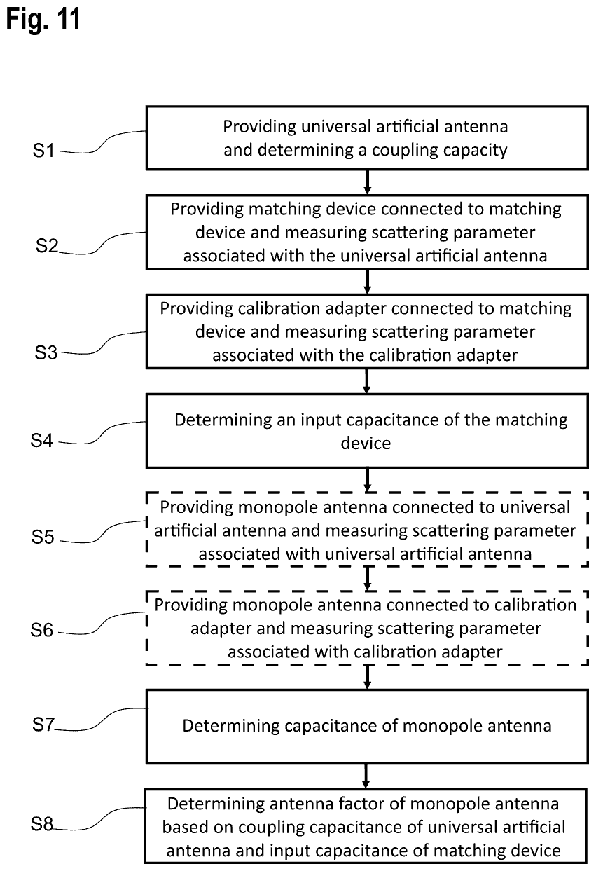

In an embodiment, the scattering parameters determined in the second measurement setup 28 and the third measurement setup 32 are used to calculate the input capacitance of the matching device 30, namely the capacitance of capacitor 34, as will be described later when referring to FIG. 11.

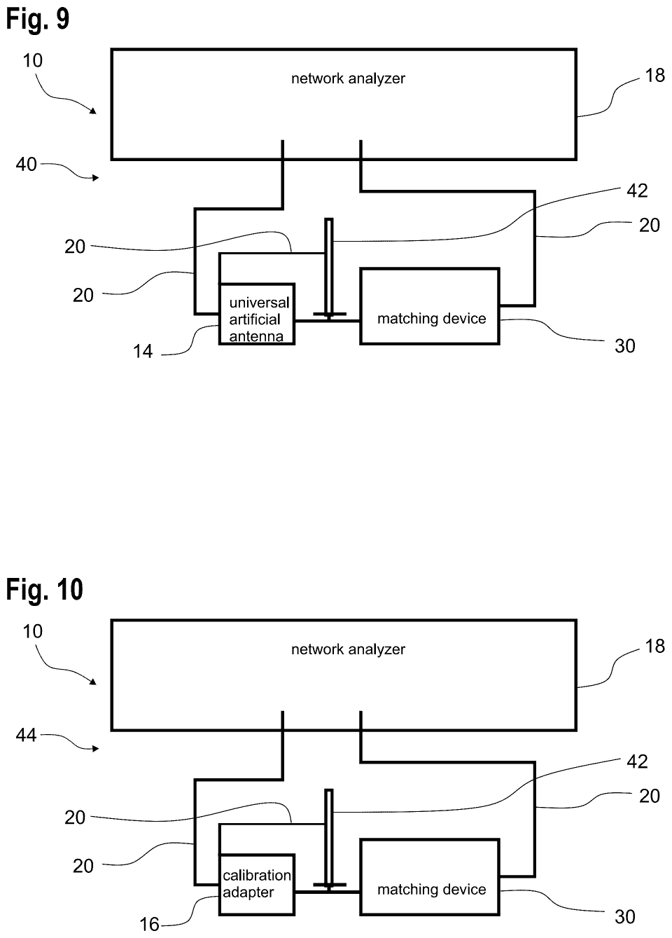

FIG. 9 schematically shows a fourth measurement setup 40 of the measurement arrangement 10, which is used to measure a scattering factor based on which the capacitance of the monopole antenna 42 can be determined. The fourth measurement setup 40 is similar to the second measurement setup 28 shown in FIG. 5. In addition to the components of the second measurement setup 28, the fourth measurement setup 40 additionally comprises the monopole antenna 42.

In this example setup, the monopole antenna 42 is connected in parallel to the universal artificial antenna 14. The monopole antenna 42 and the universal artificial antenna 14 are connected with each other by a line 20. By connecting the monopole antenna 42 in parallel to the universal artificial antenna 14, the antenna factor can be correctly calculated in a simplified manner, thereby being enabled to calibrate the monopole antenna 42 more easily.

In an embodiment, the monopole antenna 42 can be mounted either on a tripod and a ground plate (not shown) or directly on the ground plate which is placed on the ground. The tripod can have a height of 1 m.

In the fourth measurement setup 40, the network analyzer 18 includes circuitry configured to measure the scattering parameter associated with the universal artificial antenna 14 in the respective measurement setup 40. Based on the measured scattering parameter, which is again the transmission factor, namely S-parameter S₂₁, conclusions can be drawn on the capacitance of the monopole antenna 42.

In order to calculate the capacitance of the monopole antenna 42, a further measurement is performed in a fifth measurement setup 44 which is shown in FIG. 10. The fifth measurement setup 44 is similar to the fourth measurement setup 40, but the universal artificial antenna 14 has been replaced by the calibration adapter 16 in the fifth measurement setup 44. Thus, in the fifth measurement setup 44 the calibration adapter 16 is connected in parallel to the monopole antenna 42 instead of the universal artificial antenna 14 as it was the case in the fourth measurement setup 40.

The fifth measurement setup 44 is used to determine the scattering parameter associated with the calibration adapter 16, which is the transmission factor, namely S-parameter S₂₁, of the calibration adapter 16.

Based on the ratio of the scattering parameter associated with the calibration adapter 16, obtained by the fifth measurement setup 44, to the scattering parameter associated with the universal artificial antenna 14, obtained by the fourth measurement setup 40, together with the coupling capacitance of the universal artificial antenna 14 and the input capacitance of the calibration adapter 16, the capacitance of the monopole antenna 42 can be calculated. The different calculated capacitances are afterwards used to calculate the antenna factor of the monopole antenna 42. This becomes clear hereinafter while referring to the method for determining the antenna factor of the monopole antenna 42, an example of which is shown in FIG. 11. Based thereon the monopole antenna 42 can be calibrated.

In a first step S1, a universal artificial antenna 14 is provided and the coupling capacitance of the universal artificial antenna 14 is determined. Therefore, the first measurement setup 12, shown in FIG. 3, is used, in which the universal artificial antenna 14 is coupled to the calibration adapter 16. Further, the network analyzer 18 is connected with the universal artificial antenna 14 and the calibration adapter 16. The scattering parameter associated with the universal artificial antenna 14 coupled to the calibration adapter 16 is determined by the network analyzer 18, namely the scattering parameter associated with the universal artificial antenna 14 in the first measurement setup 12.

The coupling capacitance of the universal artificial antenna 14 is based on the ratio of the scattering parameter associated with the universal artificial antenna 14 coupled to the calibration adapter 16 to the frequency of a measurement signal used.

Therefore, the formula for calculating the coupling capacitance of the universal artificial antenna 14 is the following:

$${C}_{k} = \frac{{S}_{21}}{2 π \cdot f} \cdot c$$

wherein Cₖ is the coupling capacitance of the universal artificial antenna 14 and S_{21,1} is the scattering parameter associated with the universal artificial antenna 14 coupled to the calibration adapter 16, namely the scattering parameter obtained in the first measurement setup 12. In addition, a proportionality constant c is used.

In a second step S2, the matching device 30 of the measurement arrangement 10 is provided. The matching device 30 is connected with the universal artificial antenna 14, thereby replacing the calibration adapter 16. Hence, the second measurement setup 28 shown in FIG. 5 is obtained. In the second measurement setup 28, the scattering parameter associated with the universal artificial antenna 14 is measured by the network analyzer 18.

In a third step S3, the calibration adapter 16 of the measurement arrangement 10 is provided and the matching device 30 is connected to the calibration adapter 16 which replaces the universal artificial antenna 14, thereby obtaining the third measurement setup 32 shown in FIG. 6. In the third measurement setup 32, the scattering parameter associated with the calibration adapter 16 is determined by the network analyzer 18.

Based on the information already gathered, the input capacitance and the amplification of the matching device 30 can be determined, for example calculated, in a fourth step S4.

In an embodiment, the input capacitance of the matching device 30 can be determined based on the coupling capacitance of the universal artificial antenna 14, determined based on the first measurement setup 12, as well as the ratio of the scattering parameter associated with the universal artificial antenna 14, obtained in the second measurement setup 28, to the scattering parameter associated with the calibration adapter 16, obtained in the third measurement setup 32, as well as.

For example, the input capacitance of the matching device 30 can be calculated with the following formula

$${C}_{e} = ( 1 - \frac{\vert {S}_{21 , 3} \vert}{\vert {S}_{21 , 2} \vert} ) \cdot {C}_{k}$$

wherein Cₑ is the input capacitance of the matching device 30, S_{21,3} is the scattering parameter of the calibration adapter 16, obtained in the third measurement setup 32, S_{21,2} is the scattering parameter of the universal artificial antenna 14, obtained in the second measurement setup 28, and Cₖ is the coupling capacitance of the universal artificial antenna 14. Hence, the input capacitance of the matching device 30 is directly proportional to the coupling capacitance of the universal artificial antenna 14.

In a fifth step S5, the monopole antenna 42 of the measurement arrangement 10 is provided and connected to the matching device 30 and the universal artificial antenna 14, thereby providing the fourth measurement setup 40 shown in FIG. 9. Then, the scattering parameter associated with the universal artificial antenna 14 is measured by the network analyzer 18 in the fourth measurement setup 40.

In a sixth step S6, the monopole antenna 42 is provided and connected to the matching device 30 and the calibration adapter 16. In other words, the universal artificial antenna 14 was replaced in by the calibration adapter 16, thereby obtaining the fifth measurement setup 44 shown in FIG. 10. In the sixth step, the scattering parameter associated with the calibration adapter 16 is measured by the network analyzer 18 in the fifth measurement setup 44.

In a seventh step S7, the capacitance of the monopole antenna 42 can be calculated based on the coupling capacitance of the universal artificial antenna 14 calculated in the first step, the input capacitance of the matching device 30 calculated in the fourth step and the ratio of the scattering parameter associated with the universal artificial antenna 14 measured in the fifth step to the scattering parameter associated with the calibration adapter 16 measured in the sixth step.

The corresponding formula for calculating the capacitance of the monopole antenna 42 is the following:

$${C}_{a} = [ ( 1 - \frac{\vert {S}_{21 , 5} \vert}{\vert {S}_{21 , 5} \vert} ) \cdot {C}_{k} ] - {C}_{e}$$

wherein Cₐ is the capacitance of the monopole antenna 42, S_{21,5} is the scattering parameter associated with the calibration adapter 16, obtained in the fifth measurement setup 44, S_{21,4} is the scattering parameter associated with the universal artificial antenna 14, obtained in the fourth measurement setup 40, Cₖ is the coupling capacitance of the universal artificial antenna 14 and Cₑ is the input capacitance of the matching device 30.

Alternatively to determining the capacitance of the monopole antenna 42 as outlined above, e.g. by the fifth step sixth step, the capacitance of the monopole antenna 42 may be determined by a geometric model. This however typically only works for specific monopole antennas, namely cylindrical monopole antennas.

In an eighth step, the antenna factor of the monopole antenna 42 Is determined based on the capacitance of the monopole antenna 42, the coupling capacitance of the universal artificial antenna 14 and the input capacitance of the matching device 30.

In an embodiment, the formula for calculating the antenna factor of the monopole antenna 42 can utilize a correction factor when the capacitance of the universal artificial antenna 14 is not equal to the self-capacitance of the monopole antenna 42.

This correction factor is called Ke and can be calculated as follows:

$${K}_{c} = \frac{{C}_{k}}{{C}_{k} + {C}_{e}} \cdot \frac{{C}_{a} + {C}_{e}}{{C}_{a}}$$

wherein, Cₖ is the coupling capacitance of the universal artificial antenna, Cₑ is the input capacitance of the matching device and Cₐ is the capacitance of the monopole antenna.

Thus, the correction factor is the product of two different ratios of capacitances of the matching device 30, the universal artificial antenna 14 and the calibration adapter 16.

The capacitance of the monopole antenna 42, used to calculate the correction factor, can either be based on the determined capacitances of the monopole antenna 42, the universal artificial antenna 14 and the calibration adaptor 16 or it can be calculated according to a geometric model as indicated above.

As the antenna factor also depends on the height of the monopole antenna 42 above ground potential, the monopole antenna 42 can be fixed to a tripod or a ground plate 46 during the measurements, especially during the measurements in the fifth step and the sixth step, the effective height of the monopole antenna 42 also has to be included to the formula.

The formula to calculate the antenna factor of a monopole antenna 42 is the following:

$${F}_{a c} [ \frac{d B}{m} ] = 20 \cdot log \frac{1}{\vert {S}_{21 , 4} \vert} - 20 \cdot log ( 2 ) - 20 \cdot log ( {h}_{e} ) + 20 \cdot log ( {K}_{c} )$$

wherein, F_{ac} is the antenna factor, S_{21,4} is the scattering parameter of the universal artificial antenna c 14 coupled to the monopole antenna 42, which is measured in the fourth measurement setup 40, hₑ is the effective height of the monopole antenna and K_{c} is the correction factor.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

In an embodiment, one or more of the components, such as the network analyzer 18, etc., referenced above include circuitry programmed to carry out one or more steps of any of the methods disclosed herein. In an embodiment, one or more computer-readable media associated with or accessible by such circuitry contains computer readable instructions embodied thereon that, when executed by such circuitry, cause the component or circuitry to perform one or more steps of any of the methods disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible by a computing device, such as processor circuitry, etc., or other circuitry disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

It will be appreciated that in one or more embodiments, the term computer or computing device can include, for example, any computing device or processing structure, including but not limited to a processor (e.g., a microprocessor), a central processing unit (CPU), a digital signal processor (DSP), an application-specific integrated circuit (ASIC), a field-programmable gate array (FPGA), a system on a chip (SoC), a graphics processing unit (GPU) or the like, or any combinations thereof.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the detailed description herein, references to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. In addition, when a particular feature, structure, or characteristic is described in connection with an embodiment, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A method for determining an antenna factor of a monopole antenna, the method comprising the following steps:
providing a universal artificial antenna and determining a coupling capacitance of the universal artificial antenna;
providing a matching device, connecting the matching device with the universal artificial antenna, and measuring a scattering parameter associated with the universal artificial antenna,
providing a calibration adapter, connecting the matching device with the calibration adapter such that the calibration adapter replaces the universal artificial antenna, and measuring a scattering parameter associated with the calibration adapter,
determining an input capacitance of the matching device using the ratio of the scattering parameter associated with the universal artificial antenna to the scattering parameter associated with the calibration adapter;
providing a monopole antenna, connecting the monopole antenna with the matching device and the universal artificial antenna, and measuring a scattering parameter associated with the universal artificial antenna;
providing the calibration adapter, connecting the monopole antenna with the matching device and the calibration adapter such that the calibration adapter replaces the universal artificial antenna, and measuring a scattering parameter associated with the calibration adapter;
determining a capacitance of the monopole antenna based on the coupling capacitance of the universal artificial antenna, the input capacitance of the matching device, and the ratio of the scattering parameter associated with the universal artificial antenna to the scattering parameter associated with the calibration adapter; and
determining the antenna factor of the monopole antenna based on the capacitance of the monopole antenna, the coupling capacitance of the universal artificial antenna and the input capacitance of the matching device.

2. The method according to claim 1, wherein the coupling capacitance of the universal artificial antenna is determined by coupling the universal artificial antenna to the calibration adapter, and measuring a scattering parameter associated with the universal artificial antenna coupled to the calibration adapter.

3. The method according to claim 2, wherein the scattering parameter associated with the universal artificial antenna coupled to the calibration adapter is a transmission factor.

4. The method according to claim 1, wherein the capacitance of the universal artificial antenna is based on the ratio of the scattering parameter associated with the universal artificial antenna coupled to the calibration adapter to the frequency of a measurement signal used.

5. The method according to claim 1, wherein the universal artificial antenna comprises two 25Ω resistors and a capacitor, and/or wherein the calibration adapter comprises two 25Ω resistors.

6. The method according to claim 1, wherein an amplification of the matching device is also determined by using the ratio of the scattering parameter associated with the universal artificial antenna to the scattering parameter associated with the calibration adapter.

7. The method according to claim 6, wherein the input capacitance and the amplification of the matching device are directly proportional to the capacitance of the universal artificial antenna.

8. The method according to claim 1, wherein the input capacitance of the matching device is determined based on the capacitance of the universal artificial antenna and the ratio of the scattering parameter associated with the universal artificial antenna to the scattering parameter associated with the calibration adapter.

9. The method according to claim 1, wherein the matching device comprises at least a capacitor, an amplifier and an impedance.

10. The method according to claim 1, wherein the scattering parameter associated with the universal artificial antenna is a transmission factor.

11. The method according to claim 1, wherein the scattering parameter associated with the calibration adapter is a transmission factor.

12. The method according to claim 1, wherein the capacitance of the monopole antenna is determined based on the capacitance of the matching device, the capacitance of the matching device, the scattering parameter associated with the universal artificial antenna, measured when the monopole antenna is connected with the matching device and the universal artificial antenna, and the scattering parameter associated with the calibration adapter, measured when the monopole antenna is connected with the matching device and the calibration adapter.

13. The method according to claim 1, wherein the monopole antenna is connected in parallel to the universal artificial antenna.

14. The method according to claim 1, wherein the antenna factor of the monopole antenna is corrected by using a correction factor, wherein the correction factor is determined by two different ratios, wherein the ratios both depend on the capacitances of the matching device, the universal artificial antenna and the monopole antenna.

15. The method according to claim 14, wherein the correction factor is the product of the ratio of the capacitance of the universal artificial antenna to the sum of the capacitances of the universal artificial antenna and the adjustment unit; and the ratio of the sum of the capacitances of the monopole antenna and the adjustment unit to the capacitance of the monopole antenna.

16. The method according to claim 14, wherein the value of the capacitance of the monopole antenna which is used to determine the correction factor is either based on determined capacitances of the matching device, the universal artificial antenna and the monopole antenna or is determined according to a geometric model.

17. The method according to claim 1, wherein the antenna factor of the monopole antenna also depends on a height of the monopole antenna above ground potential.

18. The method according to claim 1, wherein the monopole antenna is fixed to a tripod or a ground plate during the measurement.

19. A method for determining an antenna factor of a monopole antenna, the method comprising the following steps:
providing a universal artificial antenna and determining a coupling capacitance of the universal artificial antenna;
providing a matching device, connecting the matching device with the universal artificial antenna, and measuring a scattering parameter associated with the universal artificial antenna,
providing a calibration adapter, connecting the matching device with the calibration adapter such that the calibration adapter replaces the universal artificial antenna, and measuring a scattering parameter associated with the calibration adapter,
determining an input capacitance of the matching device using the ratio of the scattering parameter associated with the universal artificial antenna to the scattering parameter associated with the calibration adapter;
providing a monopole antenna, connecting the monopole antenna with the matching device and the universal artificial antenna, and measuring a scattering parameter associated with the universal artificial antenna;
providing the calibration adapter, connecting the monopole antenna with the matching device and the calibration adapter such that the calibration adapter replaces the universal artificial antenna, and measuring a scattering parameter associated with the calibration adapter;
determining a capacitance of the monopole antenna based on a geometric model of the monopole antenna; and
determining the antenna factor of the monopole antenna based on the capacitance of the monopole antenna, the coupling capacitance of the universal artificial antenna and the input capacitance of the matching device.

20. A measurement arrangement for determining an antenna factor of a monopole antenna, wherein the measurement arrangement having different measurement setups, wherein the measurement arrangement comprises a universal artificial antenna, a calibration adapter, a matching device, a monopole antenna and a network analyzer,
wherein, in a first measurement setup for determining the capacitance of the universal artificial antenna, the universal artificial antenna is coupled to the calibration adapter;
wherein, in a second measurement setup for measuring the scattering parameter associated with the universal artificial antenna, the matching device is coupled to the universal artificial antenna, and the matching device and the artificial antenna being coupled to the network analyzer;
wherein, in a third measurement setup for measuring the scattering parameter associated with the calibration adapter, the matching device is coupled to the calibration adapter, and the matching device and the calibration adapter being coupled to the network analyzer;
wherein, in a fourth measurement setup for measuring the scattering parameter associated with the universal artificial antenna, the matching device being coupled to the monopole antenna, the universal artificial antenna being coupled to the monopole antenna, and the universal artificial antenna and the matching device being coupled to the network analyzer; and
wherein, in a fifth measurement setup for measuring the scattering parameter associated with the calibration adapter, the matching device being coupled to the monopole antenna, the calibration adapter being coupled to the monopole antenna, and the calibration adapter and the matching device being coupled to the network analyzer.
